(19) United States
(12) Patent Application Publication
(10) Pub. No.: US 2010/0032140 A1
(43) Pub. Date: Feb. 11, 2010

(54) LIQUID COOLED RACK WITH OPTIMIZED LIQUID FLOW PATH DRIVEN BY ELECTRONIC COOLING DEMAND

(75) Inventors: David W. Copeland, Mountain View, CA (US); Marlin R. Vogel, Fremont, CA (US); Andrew R. Masto, San Jose, CA (US)

Correspondence Address: OSHA LIANG L.L.P./SUN, TWO HOUSTON CENTER, 909 FANNIN, SUITE 3500, HOUSTON, TX, 77010, US

(73) Assignee: SUN MICROSYSTEMS, INC., Santa Clara, CA (US)

(21) Appl. No.: 12/187,209

(22) Filed: Aug. 6, 2008

(51) Int. Cl. F28D 15/00; G05D 23/00; H05K 7/20

(52) U.S. Cl. 165/104.33; 165/287; 361/701

(57) ABSTRACT

A cooling system for a rack-mount server including at least one blade includes a liquid cooling line, at least one adjustable valve connected to the liquid cooling line, at least one heat exchanger connected to the at least one adjustable valve, a control module connected to the at least one valve, and a feedback module connected to the control module and including a sensor configured to measure a feedback control signal. The control module is configured to adjust the at least one adjustable valve and a flow rate of liquid through the liquid cooling line based on a feedback control signal measured by the sensor.

### BACKGROUND OF INVENTION

Modem rack-mount server systems include single and multiple liquid heat exchangers that cool air through a rack-mount server system to enable the deployment of high density electronic modules (“blades”) within the system. However, individual blades or sets of blades within a rack-mount server system may not dissipate heat or power evenly. Thus, the heat exchangers must be designed to cool based on the worst case portion of an individual blade. Because various portions of a blade do not dissipate evenly, the heat exchangers may overcool lower power blades or sets of blades, resulting in increased utility costs for the entire server system.

### SUMMARY OF THE INVENTION

A cooling system for a rack-mount server including at least one blade and a system enclosure is disclosed herein. The cooling system includes a liquid cooling line, at least one adjustable valve connected to the liquid cooling line, at least one heat exchanger connected to the at least one adjustable valve, a control module connected to the at least one valve, and a feedback module connected to the control module and comprising a sensor configured to measure a feedback control signal, where the control module is configured to adjust the at least one adjustable valve and a flow rate of liquid through the liquid cooling line based on a feedback control signal measured by the sensor.

A method of controlling the power consumption of a cooling system for a rack-mount server including at least one blade, at least one heat exchanger, at least one adjustable valve, and a liquid cooling line is disclosed herein. The method includes connecting a control module to the at least one adjustable valve, measuring a feedback control signal with a feedback module comprising a sensor and connected to the control module, and adjusting the at least one adjustable valve and a flow rate of the liquid cooling line with the control module based on the feedback control signal.

### BRIEF DESCRIPTION OF DRAWINGS

FIG. 1 shows a block diagram of a rack-mount server system in accordance with embodiments disclosed herein.

FIG. 2(a) shows a block diagram of a control loop in accordance with embodiments disclosed herein.

FIG. 2(b) shows a block diagram of a control loop in accordance with embodiments disclosed herein.

FIG. 3 shows a method of controlling power consumption of a cooling system in accordance with embodiments disclosed herein.

FIG. 4 shows a computer system in accordance with embodiments disclosed herein.

### DETAILED DESCRIPTION

Specific details of the present disclosure will now be described in detail with reference to the accompanying figures.

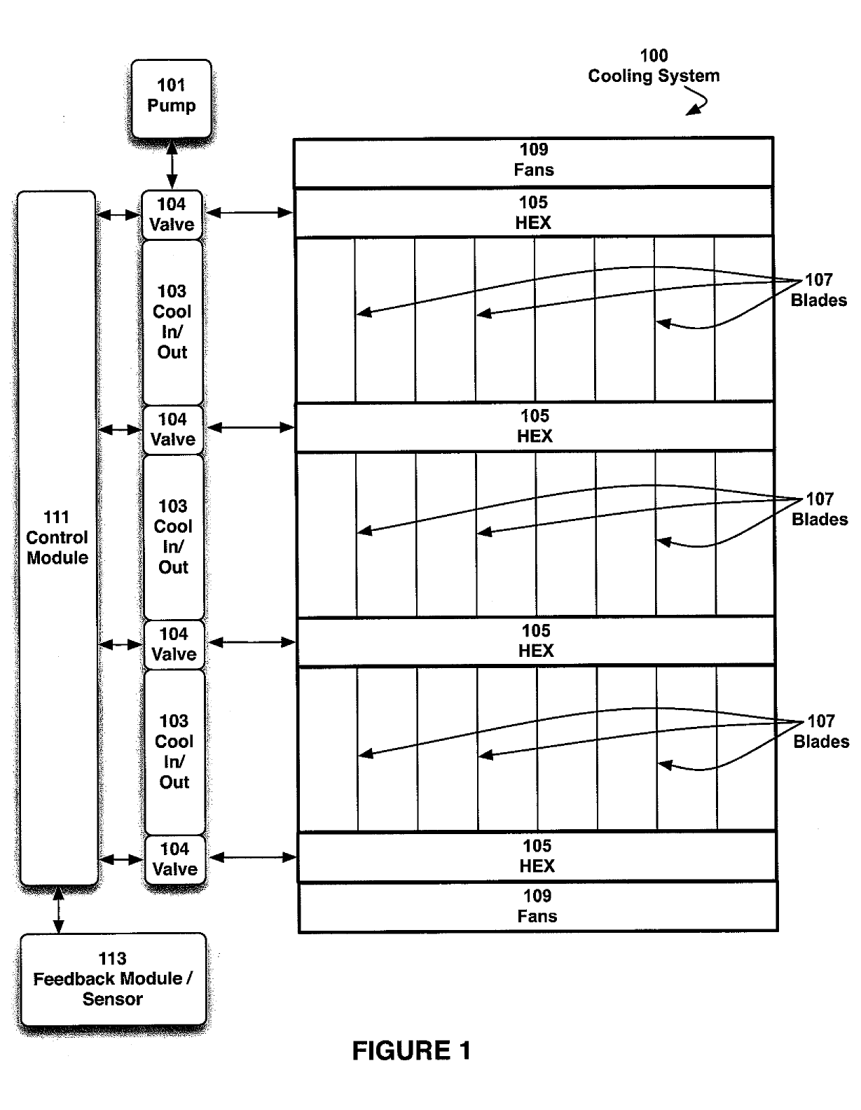

Referring now to FIG. 1, a front view of a cooling system for a rack-mount server in accordance with embodiments disclosed herein is shown. The cooling system 100 includes a pump 101, a cooling intake/outtake line 103, a plurality of valves 104, a plurality of heat exchangers (“HEX”) 105, a plurality of blades, or electronic components, 107, and a plurality of fans 109 in accordance with embodiments disclosed herein. The fans 109 are configured at the top and bottom of the rack-mount server to blow air through the heat exchangers 105 in order to cool the blades 107. The blades 107 are divided into different racks, and there at least one heat exchanger 105 corresponding to each of the different racks. Each heat exchanger 105 is configured to take in cooled liquid from the cooling intake/outtake line 103 through an adjustable valve 104, chill air flowing across the heat exchanger 105, and return warmed liquid through the valve 104 to the cooling intake/outtake line 103. The pump 101 may maintain pressure on a liquid coolant flowing through the cooling intake/outtake line 103.

The cooling capacity of each heat exchanger 105 in the cooling system 100 is proportional to the flow rate of a liquid coolant through the heat exchanger 105. Accordingly, if a set of blades corresponding to a specific heat exchanger does not generate as much heat as a set of blades corresponding to another heat exchanger, the flow rate of the liquid coolant through the specific heat exchanger may be reduced in order to reduce the total power consumption of the pump 101. Accordingly, the cooling system 100 further includes a control module 111 and a feedback module 113 that may include a sensor. The control module 111 may be configured to receive a feedback control signal corresponding to a heat exchanger 105 with the sensor from the feedback module 113 and adjust the valve 104 corresponding to the heat exchanger 105 in order to adjust the flow rate of the liquid coolant from the cooling intake/outtake line 103 through the heat exchanger 105. Advantageously, this arrangement allows the total power used by the pump 101 to be reduced when less cooling capacity is required in the cooling system 100.

The control module 111 may be any module capable of receiving a sensor measurement, determining an appropriate coolant flow rate, and outputting a control signal to an adjustable valve 104. For example, the adjustable valve 104 may be electronically controlled, and the control signal may be an electric signal transmitted from the control module 111. Examples of the control module 111 include hardware modules such as field-programmable gate arrays and software modules. The feedback module 113 may be any module capable of receiving a sensor reading and transmitting a feedback control signal to the control module 111 and may include a sensor to measure the feedback control signal from portions of the rack server. The sensor may be, for example, a temperature sensor configured to measure the temperature of one or more of the plurality of blades 107. In this case, the feedback control signal would be a temperature measurement from the temperature sensor.

Alternatively, the sensor may be, for example, a power consumption sensor configured to measure the power consumption of one or more of the plurality of blades 107. In this case, the feedback control signal would be a power consumption measurement from the power consumption sensor. Finally, the sensor may be, for example, a thermodynamic sensor configured to measure the heat flow per cubic unit through the intake and outtake lines of the cooling intake/outtake line 103. The heat flow through the outtake line is proportional to the total cooling capacity of the system. If, for example, the liquid flowing through the outtake line is cooler than necessary, the valves 104 may be adjusted to reduce the total liquid coolant flow rate through the cooling system 100. In this case, the feedback control signal would be a thermodynamic sensor measurement from the thermodynamic sensor.

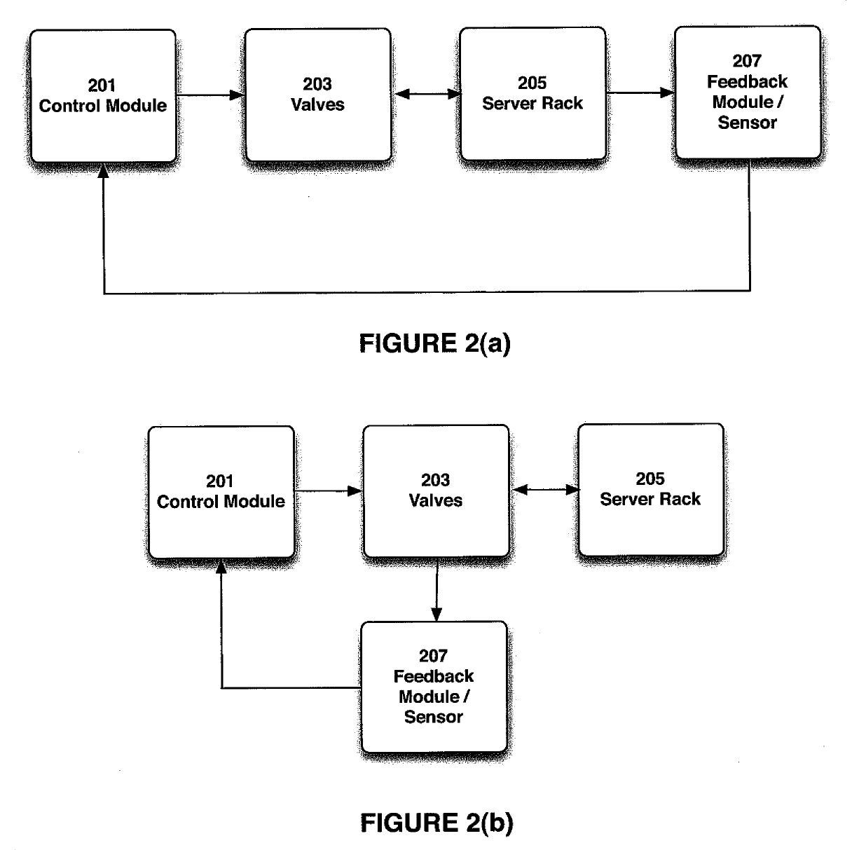

Referring now to FIG. 2(a), a block diagram of a control loop in accordance with embodiments disclosed herein is shown. A control module 201 is connected in series with a system of valves 203. The system of valves 203 connects to a liquid coolant line (not shown) and a server rack 205. A feedback control module 207 including a sensor is connected directly to the server rack 205, and also connected back to the control module 201 to return a feedback control signal based on the sensor reading from the server rack. In this example, the sensor may be either a temperature or power consumption sensor discussed above with respect to FIG. 1.

Referring now to FIG. 2(b), a block diagram of a control loop in accordance with embodiments disclosed herein is shown. A control module 201 is connected in series with a system of valves 203. The system of valves 203 connects to a liquid coolant line (not shown) and a server rack 205. A feedback control module 207 including a sensor is connected to the system of valves 203, and connected back to the control module 201 to return a feedback control signal based on the sensor reading from the server rack. In this example, the sensor may be a thermodynamic sensor discussed above with respect to FIG. 1.

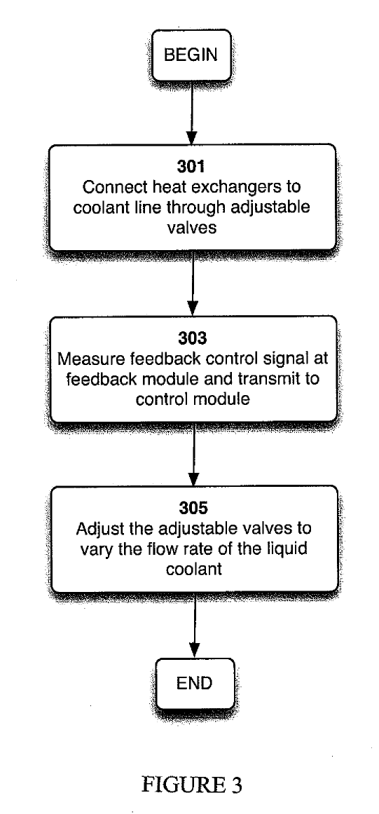

Referring now to FIG. 3, a method of controlling the power consumption of a cooling system for a rack-mount server including at least one blade, at least one heat exchanger, and a liquid cooling line in accordance with embodiments disclosed herein is shown. First, in step 301, the heat exchangers are connected to the liquid cooling line through a system of adjustable valves that are also connected to a control module. Next, in step 303, a feedback control signal is measured by a sensor disposed in a feedback module that is also connected to the control module in order to transmit the feedback control signal to the control module. The feedback control module may also transmit the feedback control signal to the control module in step 303. Finally, in step 305, the control module adjusts the adjustable valves in order to vary the flow rate of the liquid coolant through the liquid cooling line.

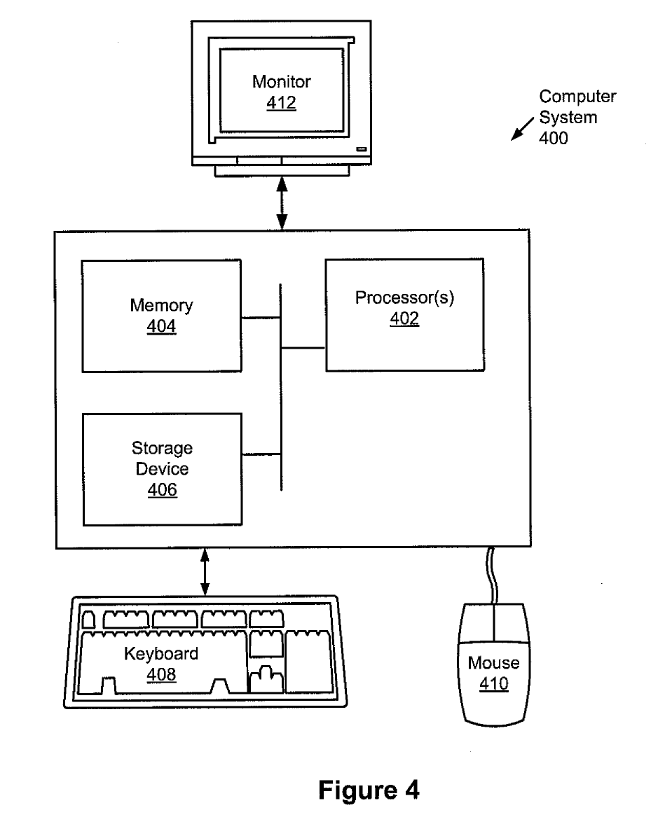

Referring now to FIG. 4, portions of the invention may be implemented in software, such as, for example, the control module and feedback module discussed above with respect to FIGS. 1, 2(a), and 2(b). These portions of the invention may be implemented on virtually any type of computer regardless of the platform being used. For example, as shown in FIG. 4, a computer system 400 includes a processor 402, associated memory 404, a storage device 406, and numerous other elements and functionalities typical of today's computers (not shown). The computer system 400 may also include input means, such as a keyboard 408 and a mouse 410, and output means, such as a monitor 412. The computer system 400 is connected to a local area network (LAN) or a wide area network (e.g., the Internet) (not shown) via a network interface connection (not shown). Those skilled in the art will appreciate that these input and output means may take other forms. Further, those skilled in the art will appreciate that one or more elements of the aforementioned computer system 400 may be located at a remote location and connected to the other elements over a network.

Further, portions of the invention may be implemented on a distributed system having a plurality of nodes, where each portion of the invention may be located on a different node within the distributed system. In one or more embodiments of the invention, the node corresponds to a computer system. Alternatively, the node may correspond to a processor with associated physical memory.

In one or more embodiments of the invention, software instructions to perform embodiments of the invention, when executed by a processor, may be stored on a computer readable medium such as a compact disc (CD), a diskette, a tape, a file, or any other computer readable storage device. Further, one or more embodiments of the invention may be implemented as an Application Program Interface (API) executing on a computer system(s), where the API includes one or more software instructions.

Embodiments of the cooling system disclosed herein may exhibit one or more of the following advantages. The cooling system disclosed herein may reduce costs for cooling a rack-mount server by reducing the pump power required for cooling the rack-mount server. The cooling system disclosed herein may also allow for cooling to be distributed according to the heat dissipation of blades or groups of blades in a rack-mount server.

While the invention has been described with respect to a limited number of embodiments, those skilled in the art, having benefit of this disclosure, will appreciate that other embodiments may be devised which do not depart from the scope of the invention as disclosed herein. Accordingly, the scope of the invention should be limited only by the attached claims.

What is claimed is:

1. A cooling system for a rack-mount server comprising at least one blade, comprising:
a liquid cooling line;
at least one adjustable valve connected to the liquid cooling line;
at least one heat exchanger connected to the at least one adjustable valve;
a control module connected to the at least one valve; and
a feedback module connected to the control module and comprising a sensor configured to measure a feedback control signal,
wherein the control module is configured to adjust the at least one adjustable valve and a flow rate of liquid through the liquid cooling line based on a feedback control signal measured by the sensor.

2. The cooling system of claim 1, wherein the at least one adjustable valve comprises an electronically controlled valve.

3. The cooling system of claim 1, wherein the sensor comprises a temperature sensor configured to measure the temperature of the at least one blade and generate the feedback control signal based on the measured temperature.

4. The cooling system of claim 1, wherein the sensor comprises a power consumption sensor configured to measure the power consumption of the at least one blade and generate the feedback control signal based on the measured power consumption.

5. The cooling system of claim 1, wherein the sensor comprises a thermodynamic sensor configured to measure the thermodynamic state of a coolant in the liquid cooling line and generate the feedback control signal based on the measured thermodynamic state.

6. The cooling system of claim 1, wherein the feedback module is further configured to adjust a flow rate from a pump connected to the liquid cooling line.

7. A method of controlling the power consumption of a cooling system for a rack-mount server comprising at least one blade, at least one heat exchanger, at least one adjustable valve, and a liquid cooling line, the method comprising:
connecting a control module to the at least one adjustable valve;
measuring a feedback control signal with a feedback module comprising a sensor and connected to the control module; and
adjusting the at least one adjustable valve and a flow rate of the liquid cooling line with the control module based on the feedback control signal.

8. The method of claim 7, wherein the at least one adjustable valve comprises an electronically controlled valve.

9. The method of claim 7, wherein the sensor comprises a temperature sensor configured to measure the temperature of the at least one blade and generate the feedback control signal based on the measured temperature.

10. The method of claim 7, wherein the sensor comprises a power consumption sensor configured to measure the power consumption of the at least one blade and generate the feedback control signal based on the measured power consumption.

11. The method of claim 7, wherein the sensor comprises a thermodynamic sensor configured to measure the thermodynamic state of a coolant in the liquid cooling line and generate the feedback control signal based on the measured thermodynamic state.

12. The method of claim 7, further comprising adjusting a flow rate from a pump connected to the liquid cooling line with the control module based on the feedback control signal.
